(19) United States
(12) Patent Application Publication
(10) Pub. No.: US 2026/0089414 A1
(43) Pub. Date: Mar. 26, 2026

(54) Amplifier Case Connector with Liquid Ingress Seal

(71) Applicant: Bose Corporation, Framingham, MA (US)

(72) Inventor: Daniel D. Hodgkins, Princeton, MA (US)

(21) Appl. No.: 18/895,579

(22) Filed: Sep. 25, 2024

(51) Int. Cl. H04R 1/02; G06F 3/16; H04R 1/28; H05K 5/00; H05K 5/06; H05K 7/20

(52) U.S. Cl. CPC H04R 1/02; G06F 3/162; H04R 1/2811; H05K 5/0026; H05K 5/06; H05K 7/20409

(57) ABSTRACT

Various implementations include amplifier cases and related assembly methods. One implementation includes a case for a vehicle amplifier, the case including: a housing for seating the amplifier; a cover for securing the amplifier in the housing; and a connector panel spanning between the housing and the cover, the connector panel having a frame at least partially surrounding a set of connectors configured to couple with a vehicle audio system, where a portion of the frame is recessed relative to the set of connectors. In particular aspects, a sealant is positioned between a portion of the housing and the frame. In further aspects, the amplifier case provides a liquid ingress seal around the vehicle amplifier at a designated submerged depth.

### TECHNICAL FIELD

This disclosure generally relates to cases for amplifiers and related assembly methods. More particularly, the disclosure relates to a case for a vehicle amplifier.

### BACKGROUND

Certain audio devices benefit from environmental protection such as liquid ingress protection. However, conventional cases for certain audio devices (e.g., amplifiers) can either provide inadequate protection and/or fail to interface effectively with external components.

### SUMMARY

All examples and features mentioned below can be combined in any technically possible way.

Various implementations include amplifier cases and related assembly methods. One aspect includes a case for a vehicle amplifier, the case including: a housing for seating the amplifier; a cover for securing the amplifier in the housing; and a connector panel spanning between the housing and the cover, the connector panel having a frame at least partially surrounding a set of connectors configured to couple with a vehicle audio system, where a portion of the frame is recessed relative to the set of connectors.

In particular aspects, a case for a vehicle amplifier includes: a housing for seating the amplifier, where the amplifier includes a printed circuit board (PCB) with an audio circuit; a cover for securing the amplifier in the housing; and a connector panel spanning between the housing and the cover, the connector panel having a frame at least partially surrounding a set of connectors configured to couple with a vehicle audio system, where the frame is separated from the PCB by a gap, and where a portion of the frame is recessed relative to the set of connectors.

In additional particular aspects, a method of assembling a vehicle audio system includes: connecting a vehicle amplifier case, housing a vehicle amplifier, to a vehicle audio interface, the vehicle amplifier case including: a housing seating the amplifier; a cover securing the amplifier in the housing; and a connector panel spanning between the housing and the cover, the connector panel having a frame at least partially surrounding a set of connectors, where a portion of the frame is recessed relative to the set of connectors, where connecting the vehicle amplifier case to the vehicle audio interface includes coupling the set of connectors with corresponding connectors in the vehicle audio interface.

Implementations may include one of the following features, or any combination thereof.

In some cases, a first section of the frame is approximately aligned with the set of connectors and a second section of the frame is recessed relative to the set of connectors.

In certain aspects, the frame includes a first wall, a second wall opposing the first wall, and sidewalls spanning between the first wall and the second wall.

In particular cases, the first wall is forward of the second wall and wherein the sidewalls are angled relative to the first wall and the second wall.

In some examples, the housing includes an interface coupled with the second wall and the sidewalls of the connector panel. In certain cases, the interface complements the second wall and the sidewalls.

In some examples, the second wall is shorter than the first wall.

In some examples, the sidewalls taper between the first wall and the second wall.

In some examples, the case further includes a lock tab extending from an upper surface of at least one of the set of connectors. In some cases, each connector includes a lock tab. In additional implementations, the lock tab is optional. In some examples, additional connectors include lock tabs.

In some examples, the lock tab is positioned to engage a retention feature in the vehicle audio system.

In some examples, the recessed portion of the frame enables access to the lock tab.

In some examples, the amplifier includes a printed circuit board (PCB), and the frame of the connector panel is separated from the PCB by a gap. In particular cases, the PCB includes an audio circuit. In certain aspects, the connector panel is forward of the PCB to enable sealing.

In some examples, the case further includes a sealant coupling the housing to the frame.

In some examples, the frame includes a set of tabs located on an outer surface thereof, where the set of tabs define channels for the sealant. In certain cases, the tabs function as standoffs or hard stops that define a minimum gap or minimum clearance for the sealant.

In some examples, the sealant contacts a portion of at least three walls of the frame, and the frame is angled to enable sealing with application of the sealant in a single orientation.

In some examples, the housing further includes a set of fins for enhancing heat transfer from the amplifier.

In some examples, the case provides a liquid ingress seal around the amplifier at a designated submerged depth.

In some examples, the designated submerged depth is approximately 0.5 meters to approximately 1.5 meters.

In some examples, the designated submerged depth is approximately one meter.

In some examples, the set of connectors includes a plurality of connectors each including a set of pins. In certain cases, a single connector is used.

In some examples, the case effectively seals the set of pins in each connector. In particular cases, the interface provides a seal, and the pins are not necessarily sealed.

In some examples, at least one of the connectors includes an 8-pin connector or a 16-pin connector.

In some examples, the amplifier includes one of: an 8-channel amplifier, a 16-channel amplifier, a 25 Volt (V) amplifier, a 40 V amplifier, or a 48 V amplifier.

In some examples, the plurality of connectors includes at least two distinct type of connector with distinct functions.

In some examples, at least one of the set of connectors includes a power pin or a speaker pin.

In some examples, a vehicle includes the case.

In some examples, a method of assembling the case includes: applying a sealant along an interface of the housing; seating the frame of the connector panel in the housing at the interface; and coupling the cover to the connector panel. In particular cases, a second bead of sealant is applied between the connector panel and the cover. In further examples, another bead of sealant is applied around couplers such as couplers in mounting holes (e.g., screws, pins, etc.).

In some examples, after the sealant has set the case is ingress resistant under submission of up to approximately one meter of water.

In some examples, the case the recessed portion of the frame enables the coupling of the set of connectors with the corresponding connectors in the vehicle audio interface.

Two or more features described in this disclosure, including those described in this summary section, may be combined to form implementations not specifically described herein.

The details of one or more implementations are set forth in the accompanying drawings and the description below. Other features, objects and benefits will be apparent from the description and drawings, and from the claims.

### BRIEF DESCRIPTION OF THE DRAWINGS

FIG. 1 shows a perspective separated view of a vehicle amplifier case according to various implementations.

FIG. 2 shows a front view of a partially separated vehicle amplifier case according to various implementations

FIG. 3 shows a side view of a vehicle amplifier case according to various implementations.

FIG. 4 shows a side view of a vehicle amplifier case coupled with a vehicle audio system connector according to various implementations.

It is noted that the drawings of the various implementations are not necessarily to scale. The drawings are intended to depict only typical aspects of the disclosure, and therefore should not be considered as limiting the scope of the implementations. In the drawings, like numbering represents like elements between the drawings.

### DETAILED DESCRIPTION

This disclosure provides, at least in part, a vehicle amplifier case that beneficially incorporates a liquid ingress seal. In various implementations, the case includes a connector panel with a set of connectors configured to couple with a vehicle audio system. In certain implementations, a portion of the frame is recessed relative to the connectors, enabling sealant to be conveniently and consistently applied to the frame to seal the amplifier interface.

Commonly labeled components in the FIGURES are considered to be substantially equivalent components for the purposes of illustration, and redundant discussion of those components is omitted for clarity.

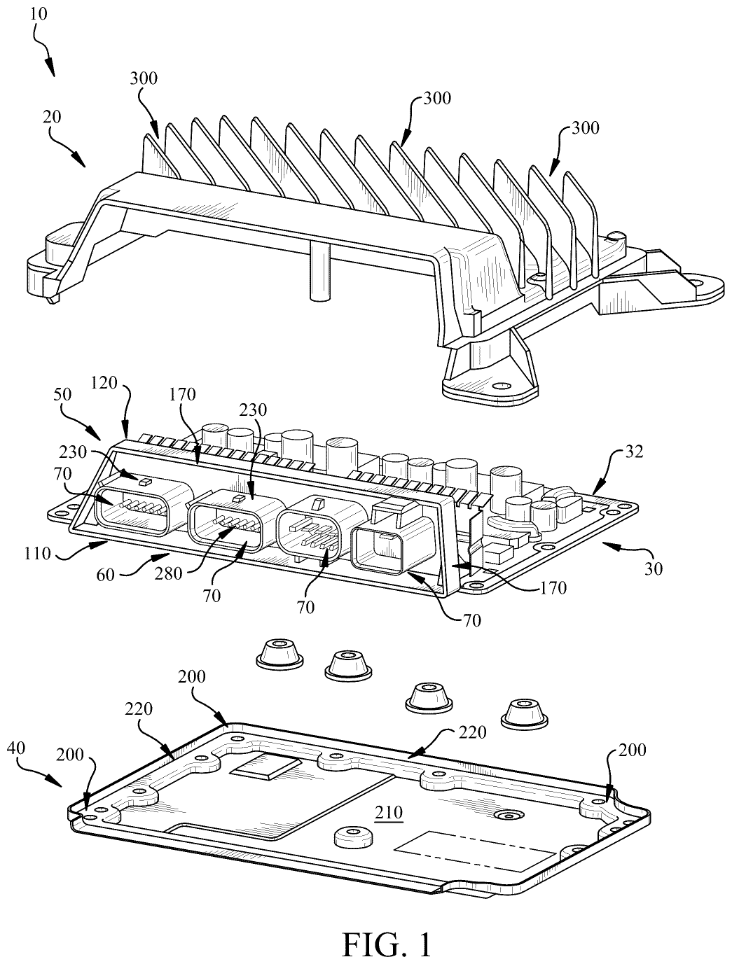

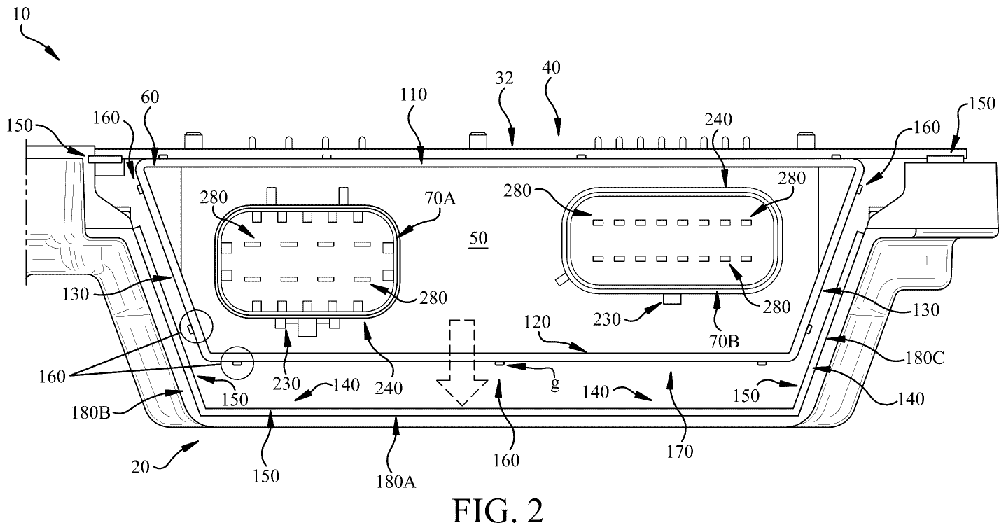

FIG. 1 shows a perspective blown-out view of an amplifier case (or, case) 10 according to various implementations. FIG. 2 shows portions of the case 10 in a partially separated end view, prior to seating an amplifier. Referring to FIGS. 1 and 2, in particular aspects, the case 10 includes a housing 20 for seating an amplifier 30. In some cases, the amplifier 30 includes a vehicle amplifier. In these implementations, the case 10 is configured to interface with a vehicle audio system to provide amplifier functions to that system. In certain examples, the amplifier 30 includes a printed circuit board (PCB) 32. The PCB 32 can include an audio circuit. In particular cases, the amplifier 30 includes one of: an 8-channel amplifier, a 16-channel amplifier, a 25 Volt (V) amplifier, a 40 V amplifier, or a 48 V amplifier.

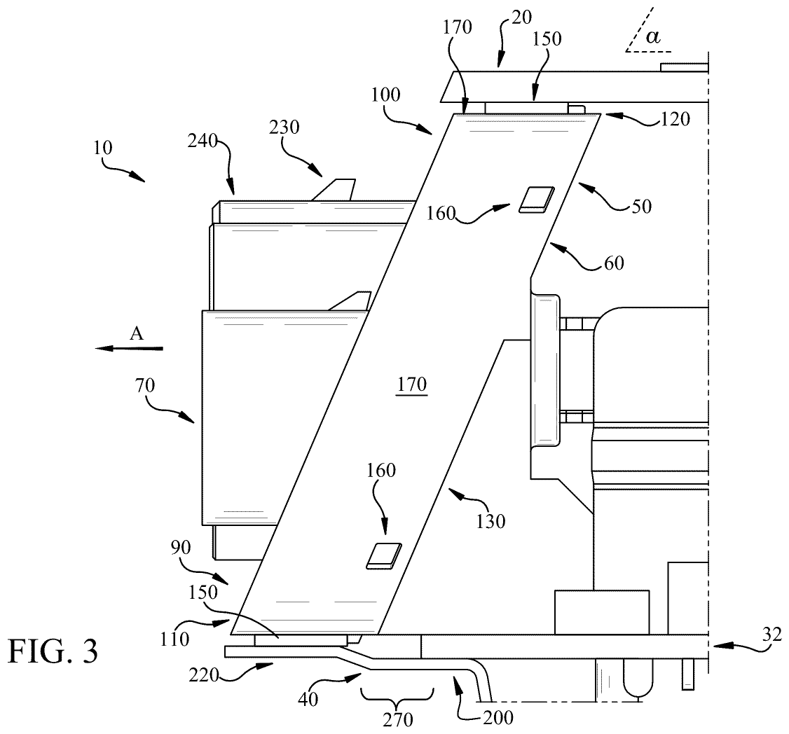

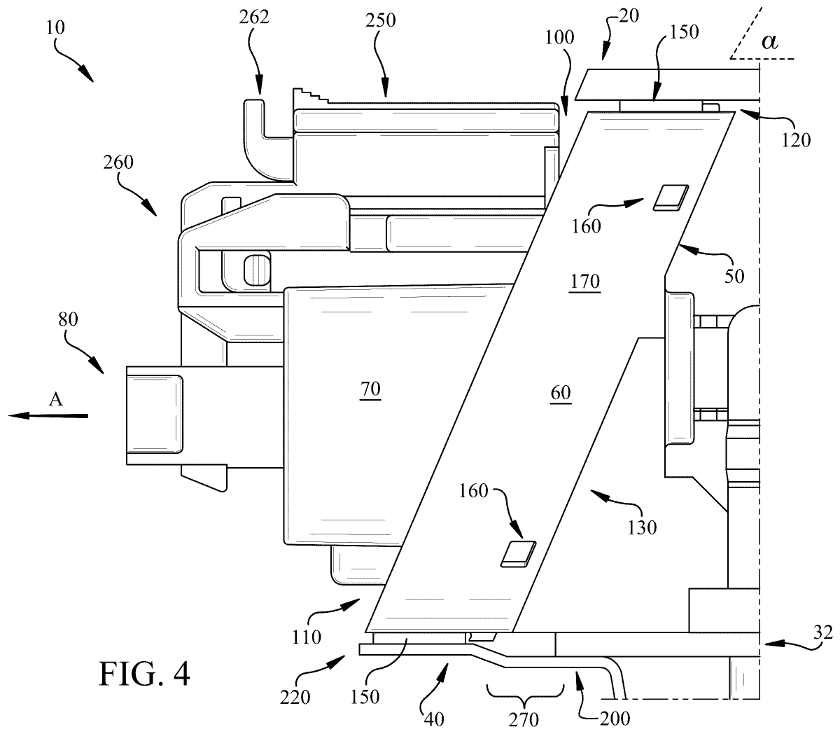

In certain aspects, the case 10 includes a cover 40 (FIG. 1) for securing the amplifier 30 in the housing 20. In some aspects, the case 10 further includes a connector panel 50 spanning between the housing 20 and the cover 40. In particular implementations, the connector panel 50 has a frame 60 that at least partially surrounds a set of connectors 70 configured to couple with the vehicle audio system. In certain implementations, a portion of the frame 60 is recessed relative to the set of connectors 70. For example, as shown in the side sectional view of the case 10 in FIG. 3, a portion of the frame 60 is recessed relative to the set of connectors 70. FIG. 4 shows a side view of the case 10 of FIG. 3, with the addition of vehicle audio system connectors 80 (and without applied sealant 150 in certain locations).

As illustrated in FIGS. 3 and 4, with particular reference to FIG. 3, a first section 90 of the frame 60 is approximately aligned (e.g., along the front-to-back axis, A) with the set of connectors 70, and a second section 100 of the frame 60 is recessed (e.g., along axis A) relative to the set of connectors 70. In certain aspects, as shown in FIGS. 1-3, the frame 60 includes a first wall 110, a second wall 120 opposing the first wall 110, and sidewalls 130 spanning between the first wall 110 and the second wall 120. In particular cases, as shown in FIG. 3, the first wall 110 is forward of the second wall 120, and sidewalls 130 are angled relative to the first wall 110 and the second wall 120 (e.g., at an angle (alpha, a) relative to the plane defined by first wall 110 or second wall 120.

In certain implementations, as shown in FIGS. 1 and 2, the second wall 120 is shorter than the first wall 110 in various implementations, e.g., as measured in a direction perpendicular to axis A). In such cases, the sidewalls 130 taper between the first wall 110 and the second wall 120.

In particular cases, as illustrated in FIGS. 1 and 2, the housing 20 includes an interface 140 coupled with the second wall 120 and the sidewalls 130 of the connector panel 50. The interface 140 can complement the second wall 120 and the sidewalls 130. In some examples, a sealant 150 couples the housing 20 to the frame 60. As can be seen in FIG. 2, the frame 60 can include a set of tabs 160 located on its outer surface 170. The tabs 160 can define channels 180 for the sealant 150, e.g., to guide the sealant 150 for bonding to the outer surface 170. In particular cases, each wall includes at least two tabs 130. In some aspects, the tabs 160 function as standoffs or hard stops that define a minimum gap (g) or minimum clearance for the sealant 150. As shown in the separated view of FIG. 2, in some cases, sealant 150 contacts a portion of at least three walls of the frame 60, e.g., second wall 120, and sidewalls 130. In certain of these cases, the frame 60 is angled to enable sealing with application of the sealant 150 in a single orientation. In certain cases, the housing 20 is placed, e.g., on a holder, stand, or surface, and the sealant 150 can be applied to three sections 180A, 180B, 180C of the interface 140 on the housing 20. In particular cases, the frame 60 can then be seated in the housing 20 (as indicated by arrow in FIG. 2), with the sealant 150 at least partially contained by the tabs 160, e.g., to set the sealant 150. This enables coupling of the frame 60 to the housing 20 without needing to reorient the components, e.g., without having to reapply sealant 150 to distinct surfaces of the interface 140. In certain additional implementations, sealant 150 can also be applied to the first wall 110 (e.g., as illustrated in FIG. 3) to aid in sealing the frame 60 to the cover 40. It is understood that the partial cutaway view in FIGS. 3 and 4 does not show sealant 150 on sidewall 130, but that sealant 150 is present along both sidewalls 130 in an assembled case 10 various implementations (e.g., as shown in FIG. 2).

As shown most clearly in FIG. 1, in some examples, the housing 20 includes a set of mounting holes (not shown) aligned with mounting holes 200 in the cover 40. In some such aspects, the mounting holes are configured to receive a coupler such as a screw, pin, nail, or other fastener for holding the housing 20 and cover 40 together. In certain cases, damping members 202 are provided between the connector panel 50 and the cover 40, e.g., to distribute compressive force across the PCB 32 and/or absorb such force. In various implementations, mounting holes 200 in the cover 40 are raised relative to a base section 210 of the cover 40. In such implementations, the base section 210 is surrounded by a lip 220 in the cover 40. In various implementations, the lip 220 can interface with the first wall 110 to aid in retaining sealant 150 at the interface, for example, forcing the sealant to conform to the first wall 110 and enhancing the bond at the interface.

In particular aspects illustrated in FIGS. 1-4, the case 10 further includes a lock tab 230 extending from an upper surface 240 of at least one the connectors 70. In some cases, each connector 70 includes a lock tab 230. The lock tab 230 can be positioned to engage a retention feature 250 in the vehicle audio system, e.g., as illustrated by the vehicle audio system connector 260 in FIG. 4. In certain cases, a locking member (e.g., sliding lock) 262 is configured to engage the lock tab 230 and prevent accidental disengagement (e.g., requiring sliding axially along A to enable disengagement of the connector 260 from connector 70). In various implementations, the angle of the frame 60 enables the vehicle audio system connector 260 to be coupled with the connector 70 while being separated from the upper surface of the PCB 32 and the interface between the second wall 120 and the housing 20. In these aspects, the housing 20 is recessed relative to the connector 260 and retention feature 250. In certain implementations, sealant 150 can be applied to those interfaces without contacting or abutting the PCB 32 or the vehicle audio system connector 260. In certain of these cases, the recessed portion 100 of the frame 60 enables access to the lock tab 230, e.g., so that the retention feature 250 can be efficiently coupled with the lock tab 230. In certain of these cases, the recessed portion 100 allows a user to access the lock tab 230 by hand and/or with a tool without interfering with the remainder of the frame 60. This can enhance coupling and/or decoupling of the frame 60 with the audio system connector 260. In other terms, the recessed portion 100 of the frame 60 enables the coupling of the set of connectors 70 with the corresponding connectors in the vehicle audio system (or, interface).

While lock tab(s) 230 are described according to certain aspects, in additional implementations, the lock tab 230 is optional. In some examples, additional connectors include lock tabs, e.g., similar to lock tab 230.

According to some implementations, as shown in FIGS. 1, 3, and 4, the frame 60 of the connector panel 50 is separated from the amplifier 30 (e.g., PCB 32) by a gap 270. In some aspects, the connector panel 50 is forward of the PCB 32 (e.g., along axis A) to enable sealing.

As described herein, the case 10 can provide a seal around the amplifier 30 to beneficially prevent liquid ingress. In certain implementations, the case 10 provides a liquid ingress seal around the amplifier 30 at a designated submerged depth. In some examples, the designated submerged depth is approximately 0.5 meters to approximately 1.5 meters. In particular examples, the designated submerged depth is approximately one meter.

As also illustrated herein, e.g., in FIGS. 1 and 2, the set of connectors 70 includes a plurality of connectors 70 each including a set of pins 280. In some examples, e.g., as illustrated in FIG. 2, an 8-pin connector 70A and/or a 16-pin connector 70B are present. In certain cases, a single connector 70 is present. In certain aspects, at least two distinct type of connectors 70 are present, with distinct functions. For example, at least one of the connectors 70 can include a power pin, and at least one of the connectors 70 can include a speaker pin. In certain aspects, the case 10 effectively seals the pins 280 in each connector 70. For example, the interface 140 can provide an effective seal for the connectors 70 (including pins 280), such that the pins 280 themselves need not be separately sealed.

In further implementations, e.g., as shown in FIG. 1, the housing 20 can further include a set of fins 300 for enhancing heat transfer from the amplifier 30. In certain aspects, the fins 300 are located on one or more surfaces of the housing 20. In some examples, the fins are on a side of the housing 20 that opposes the cover 40. In particular implementations, a vehicle includes the case 10, and the fins 300 aid in heat transfer from the amplifier 30, e.g., to a compartment of the vehicle and/or to an area external to the vehicle.

FIGS. 1-4 provide various views of aspects of an amplifier case 10 according to aspects of the disclosure. Certain implementations include a method of assembling the case 10, including processes such as: P1) applying a sealant 150 along an interface 140 of the housing 20. In certain aspects, a first bead of sealant 150 is applied along sections 180A, 180B, 180C (FIG. 2). In particular aspects, at this time, or at a later time, sealant 150 can also be applied in various grooves in housing 20 (not necessarily shown). In another process (P2), the frame 60 of the connector panel 50 is then seated in the housing 20 at the interface 140, e.g., by aligning and placing the frame 60 relative to the sections 180A, 180B, 180C. In another process (P3) the cover 40 is coupled to the connector panel 50, e.g., by inserting and connecting via mounting holes 200. In particular cases, a second bead of sealant 150 is applied between the connector panel 50 and the cover 40, e.g., as part of coupling either before or after securing connectors via mounting holes 200 (FIG. 3). In further examples, another bead of sealant 150 is applied around couplers such as couplers (e.g., screws, pins, etc.) in mounting holes 200. Further, as noted herein, sealant 150 can be applied along the interface between lip 220 and the housing 20, e.g., as illustrated in simplified form in FIG. 2. As noted herein, in some examples, after the sealant 150 has set the case 10 is ingress resistant under submission of up to approximately one meter of water. In some aspects, the case 10 is ingress resistant to comply with an ingress protection code such as IP code defined by the International Electrotechnical Commission (IEC). In some aspects, the case 10 is ingress resistant up to approximately IPx7, and in some aspects, up to approximately IPx8.

Additional particular implementations include approaches for assembling a vehicle audio system. In some of these aspects, the vehicle amplifier case 10 is coupled with a vehicle audio interface at the vehicle audio system, for example, by coupling connectors 70 with corresponding connectors 80 in the vehicle audio interface. It is understood that the vehicle audio interface can include vehicle audio system components such as audio devices and associated electronic components such as a transducer (or, driver), controller (e.g., one or more control circuits such as found on printed circuit boards (PCBs), and communications equipment such as one or more wireless communication devices and associated chips/chipsets. In particular implementations, the audio devices can also include passive radiators in addition to driven transducers.

As noted herein, the case 10 disclosed according to various implementations provides numerous benefits relative to conventional devices. For example, the case 10 can enable efficient and effective connection between amplifier circuit connectors and a vehicle audio system. Further, the case provides a liquid ingress seal to enhance durability and/or reliability of the amplifier circuit. Further, assembly of the case 10 to provide the liquid ingress seal can be performed efficiently and with easily replicated processes.

It is understood that the relative proportions, sizes and shapes of the case 10 and components and features thereof as shown in the FIGURES included herein can be merely illustrative of such physical attributes of these components. That is, these proportions, shapes and sizes can be modified according to various implementations to fit a variety of products, e.g., additional types of device connectors and/or interfaces that can benefit from sealing.

The term “approximately” as used with respect to values herein can allot for a nominal variation from absolute values, e.g., of several percent or less. Where the term “comprising” is used in the present description and claims, it does not exclude other elements or operations. The term “based on” (as in “A is based on B”) is used to indicate any of its ordinary meanings, including the cases (i) “based on at least” (e.g., “A is based on at least B”) and, if appropriate in the particular context, (ii) “equal to” (e.g., “A is equal to B”). Similarly, the term “in response to” is used to indicate any of its ordinary meanings, including “in response to at least.”

In various implementations, components described as being “coupled” to one another can be joined along one or more interfaces. In some implementations, these interfaces can include junctions between distinct components, and in other cases, these interfaces can include a solidly and/or integrally formed interconnection. That is, in some cases, components that are “coupled” to one another can be simultaneously formed to define a single continuous member. However, in other implementations, these coupled components can be formed as separate members and be subsequently joined through known processes (e.g., soldering, fastening, ultrasonic welding, bonding). In various implementations, electronic components described as being “coupled” can be linked via conventional hard-wired and/or wireless means such that these electronic components can communicate data with one another. Additionally, sub-components within a given component can be considered to be linked via conventional pathways, which may not necessarily be illustrated.

A number of implementations have been described. Nevertheless, it will be understood that additional modifications may be made without departing from the scope of the inventive concepts described herein, and, accordingly, other implementations are within the scope of the following claims.

I claim:

1. A case for a vehicle amplifier, the case comprising:
a housing for seating the amplifier;
a cover for securing the amplifier in the housing; and
a connector panel spanning between the housing and the cover, the connector panel having a frame at least partially surrounding a set of connectors configured to couple with a vehicle audio system,
wherein a portion of the frame is recessed relative to the set of connectors.

2. The case of claim 1, wherein a first section of the frame is approximately aligned with the set of connectors and a second section of the frame is recessed relative to the set of connectors.

3. The case of claim 1, wherein the frame includes a first wall, a second wall opposing the first wall, and sidewalls spanning between the first wall and the second wall, wherein the first wall is forward of the second wall, the sidewalls are angled relative to the first wall and the second wall, and the second wall is shorter than the first wall,
wherein the housing includes an interface coupled with the second wall and the sidewalls of the connector panel.

4. The case of claim 3, wherein the sidewalls taper between the first wall and the second wall.

5. The case of claim 1, further comprising at least one lock tab extending from an upper surface of at least one of the set of connectors.

6. The case of claim 5, wherein the at least one lock tab is positioned to engage a retention feature in the vehicle audio system, and
wherein the recessed portion of the frame enables access to the at least one lock tab.

7. The case of claim 1, wherein the amplifier includes a printed circuit board (PCB), and wherein the frame of the connector panel is separated from the PCB by a gap.

8. The case of claim 1, further comprising a sealant coupling the housing to the frame,
wherein the frame includes a set of tabs located on an outer surface thereof, the set of tabs defining channels for the sealant,
wherein the sealant contacts a portion of at least three walls of the frame, and wherein the frame is angled to enable sealing with application of the sealant in a single orientation.

9. The case of claim 1, wherein the housing further includes a set of fins for enhancing heat transfer from the amplifier.

10. The case of claim 1, wherein the case provides a liquid ingress seal around the amplifier at a designated submerged depth,
wherein the designated submerged depth is approximately 0.5 meters to approximately 1.5 meters.

11. The case of claim 1, wherein the set of connectors includes a plurality of connectors each including a set of pins, wherein the case effectively seals the set of pins in each connector.

12. The case of claim 11, wherein:
(i) at least one of the connectors includes an 8-pin connector or a 16-pin connector,
(ii) the amplifier includes one of: an 8-channel amplifier, a 16-channel amplifier, a 25 Volt (V) amplifier, a 40 V amplifier, or a 48 V amplifier
(iii) the plurality of connectors includes at least two distinct type of connector with distinct functions, or
(iv) at least one of the connectors includes a power pin or a speaker pin.

13. A vehicle comprising the case of claim 1.

14. A method of assembling the case of claim 1, further including:
applying a sealant along an interface of the housing;
seating the frame of the connector panel in the housing at the interface; and
coupling the cover to the connector panel.

15. The method of claim 14, wherein after the sealant has set the case is ingress resistant under submission of up to approximately one meter of water.

16. A case for a vehicle amplifier, the case comprising:
a housing for seating the amplifier, wherein the amplifier includes a printed circuit board (PCB) with an audio circuit;
a cover for securing the amplifier in the housing; and
a connector panel spanning between the housing and the cover, the connector panel having a frame at least partially surrounding a set of connectors configured to couple with a vehicle audio system,
wherein the frame is separated from the PCB by a gap, and wherein a portion of the frame is recessed relative to the set of connectors.

17. The case of claim 16, further comprising a sealant coupling the housing to the frame.

18. The case of claim 16, wherein the case provides a liquid ingress seal around the amplifier at a designated submerged depth, wherein the designated submerged depth is approximately 0.5 meters to approximately 1.5 meters.

19. A method of assembling a vehicle audio system, the method comprising:
connecting a vehicle amplifier case, housing a vehicle amplifier, to a vehicle audio interface, the vehicle amplifier case including
a housing seating the amplifier;
a cover securing the amplifier in the housing; and
a connector panel spanning between the housing and the cover, the connector panel having a frame at least partially surrounding a set of connectors,
wherein a portion of the frame is recessed relative to the set of connectors,
wherein connecting the vehicle amplifier case to the vehicle audio interface includes coupling the set of connectors with corresponding connectors in the vehicle audio interface.

20. The method of claim 19, wherein the recessed portion of the frame enables the coupling of the set of connectors with the corresponding connectors in the vehicle audio interface, and wherein the vehicle amplifier case is ingress resistant under submission of up to approximately one meter of water.
